(19) United States
(12) Patent Application Publication
(10) Pub. No.: US 2022/0408528 A1
(43) Pub. Date: Dec. 22, 2022

(54) LIGHT EMITTING ELEMENT DRIVING CIRCUIT AND LIGHT EMITTING DEVICE

(71) Applicant: Sony Semiconductor Solutions Corporation, Kanagawa (JP)

(72) Inventor: Shouichi Kuroki, Kumamoto (JP)

(21) Appl. No.: 17/772,346

(22) PCT Filed: Nov. 9, 2020
(86) PCT No.: PCT/JP2020/041781

§ 371 Date: Apr. 27, 2022

(30) Foreign Application Priority Data
Nov. 19, 2019 (JP) 2019-208755

(51) Int. Cl. H05B 45/345; H05B 47/10

(52) U.S. Cl. CPC H05B 45/345; H05B 47/10

(57) ABSTRACT

A light emitting element driving circuit (2) according to the present disclosure includes a constant current circuit (10), a switch (20), and a booster circuit (30). The constant current circuit (10) supplies a constant current (Ia) from a power supply voltage (Vcc) to a light emitting element (3). The switch (20) disconnects or connects a current (I1) flowing through the light emitting element (3) based on an external signal. The booster circuit (30) boosts a voltage between the power supply voltage (Vcc) and the light emitting element (3) in synchronization with a timing at which the light emitting element (3) is turned on.

### FIELD

The present disclosure relates to a light emitting element driving circuit and a light emitting device.

### BACKGROUND

A light emitting device including a light emitting element such as a laser diode (LD) or a light emitting diode (LED) is provided with a light emitting element driving circuit that supplies a driving current to the light emitting element (see, for example, Patent Literature 1).

### CITATION LIST

### Patent Literature

Patent Literature 1: JP 2003-60289 A

### SUMMARY

### Technical Problem

The present disclosure proposes a light emitting element driving circuit and a light emitting device capable of achieving both shortening of a rise time of a light emitting element and reduction of power consumption.

### Solution to Problem

According to the present disclosure, there is provided a light emitting element driving circuit. The light emitting element driving circuit includes a constant current circuit, a switch, and a booster circuit. The constant current circuit supplies a constant current to a light emitting element from a power supply voltage. The switch disconnects or connects a current flowing through the light emitting element based on an external signal. The booster circuit boosts a voltage between the power supply voltage and the light emitting element in synchronization with a timing at which the light emitting element is turned on.

### BRIEF DESCRIPTION OF DRAWINGS

FIG. 1 is a circuit diagram illustrating a configuration example of a light emitting device and a light emitting element driving circuit according to an embodiment of the present disclosure.

FIG. 2 is a circuit diagram illustrating a configuration example of a light emitting device and a light emitting element driving circuit of a first reference example.

FIG. 3 is a timing chart illustrating an operation example of the light emitting element driving circuit of the first reference example.

FIG. 4 is a circuit diagram illustrating a configuration example of a light emitting device and a light emitting element driving circuit of a second reference example.

FIG. 5 is a timing chart illustrating an operation example of the light emitting element driving circuit of the second reference example.

FIG. 6 is a timing chart illustrating an operation example of the light emitting element driving circuit according to the embodiment of the present disclosure.

FIG. 7 is a circuit diagram illustrating a configuration example of the light emitting device and the light emitting element driving circuit according to the embodiment of the present disclosure.

FIG. 8 is a timing chart illustrating an operation example of each signal according to the embodiment of the present disclosure.

FIG. 9 is a circuit diagram illustrating a configuration example of a light emitting device and a light emitting element driving circuit according to a first modification of the embodiment of the present disclosure.

FIG. 10 is a circuit diagram illustrating a configuration example of a light emitting device and a light emitting element driving circuit according to a second modification of the embodiment of the present disclosure.

FIG. 11 is a circuit diagram illustrating a configuration example of a light emitting device and a light emitting element driving circuit according to a third modification of the embodiment of the present disclosure.

### DESCRIPTION OF EMBODIMENTS

Hereinafter, embodiments of the present disclosure will be described in detail with reference to the drawings. Note that, in the following embodiments, the same parts are denoted by the same reference numerals so that redundant description can be omitted.

A light emitting device including a light emitting element such as a laser diode (LD) or a light emitting diode (LED) is provided with a light emitting element driving circuit that supplies a driving current to the light emitting element.

In addition, in this light emitting element driving circuit, there is a known technique of shortening a rise time when the light emitting element emits light by flowing a weak current before causing the light emitting element to emit light.

However, in the above-described technique, there is a problem that the power consumption of the light emitting device increases because a current flows through the light emitting element even in a state where the light emitting element is not emitting light.

Therefore, it is expected to provide a technique capable of overcoming the above-described problem and achieving both shortening of the rise time of the light emitting element and reduction of power consumption.

[Configuration of a Light Emitting Device and a Light Emitting Element Driving Circuit]

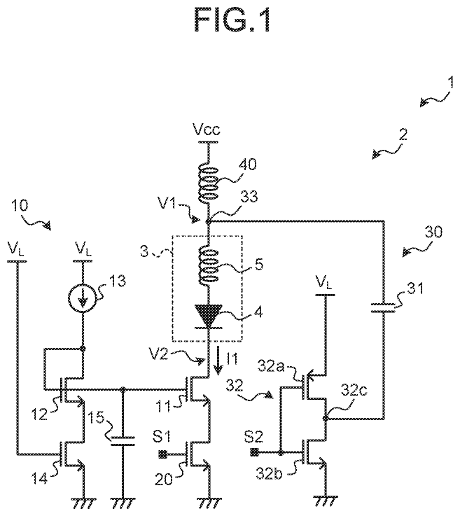

First, specific configurations of a light emitting device 1 and a light emitting element driving circuit 2 will be described with reference to FIG. 1. FIG. 1 is a circuit diagram illustrating a configuration example of the light emitting device 1 and the light emitting element driving circuit 2 according to an embodiment of the present disclosure.

As illustrated in FIG. 1, the light emitting device 1 includes the light emitting element driving circuit 2 and a light emitting element 3. In the light emitting device 1, the light emitting element 3 emits light when a driving current is supplied from the light emitting element driving circuit 2 to the light emitting element 3.

The light emitting element 3 is, for example, a laser diode or an LED. The light emitting element 3 has a diode 4 that emits light when a driving current is supplied from the light emitting element driving circuit 2, and a parasitic inductor 5. In the light emitting element 3, the diode 4 and the parasitic inductor 5 are connected in series.

The light emitting element driving circuit 2 includes a constant current circuit 10, a switch 20, a booster circuit 30, and an inductor element 40. The constant current circuit 10 supplies a predetermined constant current to the light emitting element 3 from a power supply voltage Vcc. The power supply voltage Vcc is a predetermined voltage (for example, 3.3 (V) or 5 (V)) that can cause the light emitting element 3 to emit light.

The switch 20 disconnects or connects the current flowing through the light emitting element 3 based on an external signal. The booster circuit 30 boosts a voltage between the power supply voltage Vcc and the light emitting element 3 in synchronization with the timing at which the light emitting element 3 is turned on. The inductor element 40 is provided between the power supply voltage Vcc and the light emitting element 3.

Next, a specific circuit configuration of each part of the light emitting device 1 will be described. The anode of the diode 4 of the light emitting element 3 is connected to the power supply voltage Vcc via the parasitic inductor 5 and the inductor element 40 connected in series.

The cathode of the diode 4 is grounded via an N-type transistor 11 and the switch 20 connected in series. The N-type transistor 11 is a part of the constant current circuit 10, and the switch 20 is constituted by an N-type transistor.

The constant current circuit 10 has the N-type transistor 11, an N-type transistor 12, a constant current source 13, an N-type transistor 14, and a capacitor 15. The N-type transistor 11 and the N-type transistor 12 are high breakdown voltage transistors (for example, LDMOS) having substantially equal element characteristics, and constitute a current mirror.

That is, the gate of the N-type transistor 11 is connected to the gate of the N-type transistor 12, and the gate of the N-type transistor 12 is connected to the drain of the N-type transistor 12.

In addition, the drain of the N-type transistor 12 is connected to a voltage V_{L} for logic operation via the constant current source 13, and the source of the N-type transistor 12 is grounded via the N-type transistor 14. The voltage V_{L} for logic operation is, for example, 1.8 (V).

Furthermore, a voltage V_{L} for logic operation is connected to the gate of the N-type transistor 14, and the gate of the N-type transistor 11 and the gate of the N-type transistor 12 are grounded via the capacitor 15.

With such a circuit configuration, the constant current circuit 10 can cause a constant current to flow through the N-type transistor 11 based on the constant current flowing from the constant current source 13 to the N-type transistor 12. As a result, the constant current circuit 10 can supply the constant current to the light emitting element 3 connected in series with the N-type transistor 11.

In the constant current circuit 10 according to the embodiment, the N-type transistor 11 and the N-type transistor 12 preferably have substantially equal element characteristics, and the N-type transistor 14 preferably has substantially equal element characteristics as the switch 20.

With such a configuration, the constant current circuit 10 according to the embodiment can supply a stable constant current whose mirror ratio of the current mirror is close to the element size to the light emitting element 3.

The drain of the switch 20 constituted by an N-type transistor is connected to the light emitting element 3 via the N-type transistor 11 of the constant current circuit 10, and the source of the switch 20 is grounded. In addition, a signal S1 from a control unit (not illustrated) is input to the gate of the switch 20. The signal S1 is an example of the external signal.

When the signal S1 is at a high level, since the switch 20 is in a conductive state, a predetermined constant current is supplied from the power supply voltage Vcc to the light emitting element 3, and thus the light emitting element 3 is turned on. When the signal S1 is at a low level, since the switch 20 is in a disconnected state, the constant current is not supplied from the power supply voltage Vcc to the light emitting element 3, and thus the light emitting element 3 is turned on.

The booster circuit 30 has a capacitor 31 and an inverter 32. The inverter 32 has a P-type transistor 32a and an N-type transistor 32b.

The source of the P-type transistor 32a is connected to a voltage V_{L} for logic operation, and the drain of the P-type transistor 32a is connected to the drain of the N-type transistor 32b via a node 32c. The node 32c corresponds to the output terminal of the inverter 32. In addition, the source of the N-type transistor 32b is grounded.

A signal S2, which is another external signal, is input to the gate of the P-type transistor 32a and the gate of the N-type transistor 32b, which are the input terminal of the inverter 32. Details of the signal S2 will be described later.

The capacitor 31 is provided between the node 32c, which is the output terminal of the inverter 32, and a node 33 provided between the power supply voltage Vcc and the light emitting element 3 (specifically, between the inductor element 40 and the light emitting element 3).

[Operation of the Light Emitting Element Driving Circuit]

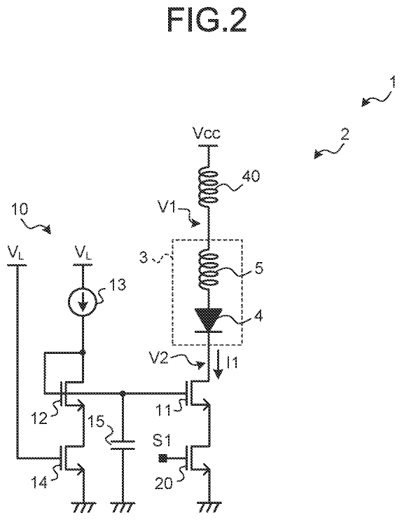

Next, the operation of the light emitting element driving circuit 2 according to the embodiment will be described with reference to FIGS. 2 to 8. In the following description, in order to facilitate understanding, the embodiment is compared with a first reference example and a second reference example.

First, the first reference example of the present disclosure will be described. FIG. 2 is a circuit diagram illustrating a configuration example of a light emitting device 1 and a light emitting element driving circuit 2 of the first reference example. As illustrated in FIG. 2, the light emitting device 1 of the first reference example has the same configuration as that of the embodiment except that the booster circuit 30 is not provided.

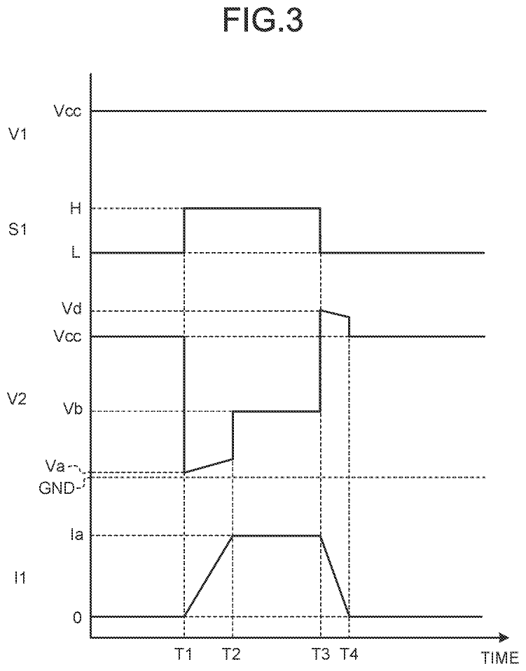

Next, the operation of the light emitting element driving circuit 2 of the first reference example will be described with reference to FIG. 3 in addition to FIG. 2. FIG. 3 is a timing chart illustrating an operation example of the light emitting element driving circuit 2 of the first reference example, and illustrates a voltage V1, a signal S1, a voltage V2, and a current I1.

Here, as illustrated in FIG. 2, the voltage V1 is a voltage on the input side (that is, the anode side of the diode 4) of the light emitting element 3, and the signal S1 is an external signal input to the gate of the switch 20.

In addition, the voltage V2 is a voltage on the output side (that is, the cathode side of the diode 4) of the light emitting element 3, and the current I1 is an output current (that is, the current output from the cathode of the diode 4) of the light emitting element 3.

As illustrated in FIG. 3, in the initial state, the signal S1 is at a low level and thus the switch 20 (see FIG. 2) is in a disconnected state. Therefore, in the initial state, the output current (the current I1) of the light emitting element 3 is zero, and the light emitting element 3 is in a turn-off state.

In addition, in the initial state, the current I1 is zero and thus both the voltage V1 on the input side and the voltage V2 on the output side of the light emitting element 3 have values substantially equal to a power supply voltage Vcc.

Next, when the signal S1 is switched from a low level to a high level at a time T1, the switch 20 is brought into a conductive state, and thus a current starts to flow through the light emitting element 3. This causes the value of the current I1 to gradually increase from the time T1.

In addition, when the current starts to flow through the light emitting element 3 at the time T1, a potential difference is generated between the input side and the output side of the light emitting element 3, and thus the voltage V2 on the output side decreases. Furthermore, since the parasitic inductor 5 is present in the light emitting element 3, a great voltage drop occurs in the light emitting element 3 due to a change in the value of the current flowing through the parasitic inductor 5.

As a result, the voltage V2 on the output side of the light emitting element 3 greatly decreases to a voltage Va near a ground voltage (GND in FIG. 3) after the time T1.

The voltage V2 can be regarded as the output voltage of the constant current circuit 10 that is a current mirror circuit, and when the output voltage (the voltage V2) of the current mirror circuit greatly decreases in this manner, the mirror ratio of the constant current circuit 10 cannot be maintained.

When the mirror ratio of the constant current circuit 10 collapses, it becomes difficult to flow a current necessary for the light emitting element 3 from the constant current circuit 10, and thus the increase in the current I1 is suppressed. Therefore, in the first modification, the current I1 finally reaches a predetermined constant current Ia at a time T2.

As described above, in the first modification, since a great voltage drop occurs in the light emitting element 3 due to the parasitic inductor 5 in the light emitting element 3, it is difficult to shorten the rise time (T2-T1 in FIG. 3) of the light emitting element 3.

The flow after the time T2 will be described. When the current I1 reaches the predetermined constant current Ia at the time T2, the voltage drop due to the parasitic inductor 5 no longer occurs, and thus the voltage V2 on the output side of the light emitting element 3 increases and becomes constant at a voltage Vb. Then, the light emitting element 3 maintains the lighting state.

Next, when the signal S1 is switched from a high level to a low level at a time T3, the switch 20 is brought into a disconnected state, and thus the current flowing through the light emitting element 3 starts to decrease. As a result, the value of the current I1 gradually decreases from the time T3.

In addition, when the current in the light emitting element 3 starts to decrease at the time T3, a potential difference between the input side and the output side of the light emitting element 3 becomes small, and thus the voltage V2 on the output side increases. Furthermore, since the parasitic inductor 5 is present in the light emitting element 3, a great voltage rise occurs in the light emitting element 3 due to a change in the value of the current flowing through the parasitic inductor 5.

As a result, the voltage V2 on the output side of the light emitting element 3 increases to a voltage Vd exceeding the power supply voltage Vcc after the time T3.

Then, when the value of the current I1 becomes zero at a time T4, the light emitting element 3 is turned off and returns to the initial state. In addition, when the current I1 becomes constant at zero at the time T4, the voltage rise due to the parasitic inductor 5 no longer occurs, and thus the voltage V2 on the output side of the light emitting element 3 returns to a value substantially equal to the power supply voltage Vcc.

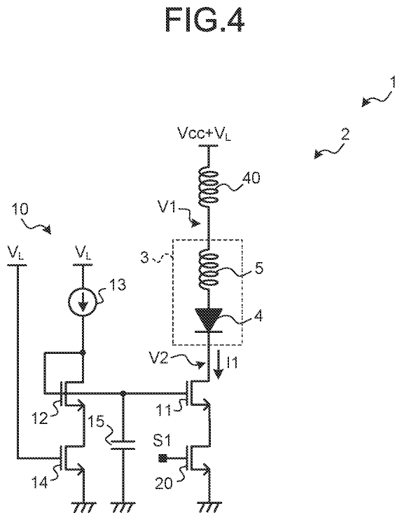

Next, the second reference example of the present disclosure will be described. FIG. 4 is a circuit diagram illustrating a configuration example of a light emitting device 1 and a light emitting element driving circuit 2 of the second reference example. As illustrated in FIG. 4, the light emitting device 1 of the second reference example has the same configuration as that of the embodiment except that the booster circuit 30 is not provided and the power supply voltage is not Vcc but Vcc+V_{L}.

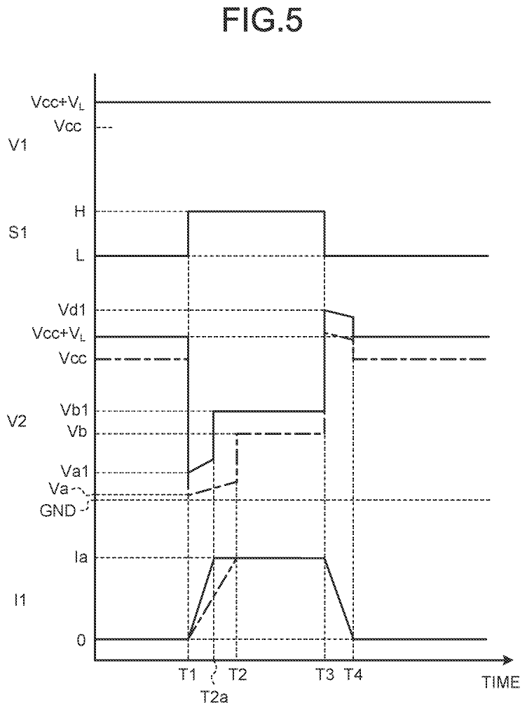

Next, the operation of the light emitting element driving circuit 2 according to the second reference example will be described with reference to FIG. 5 in addition to FIG. 4. FIG. 5 is a timing chart illustrating an operation example of the light emitting element driving circuit 2 of the second reference example, and illustrates the voltage V1, the signal S1, the voltage V2, and the current I1 as in the first reference example.

In FIG. 5, in order to facilitate understanding, changes in the voltage V2 and the current I1 in the first reference example are indicated by chain lines.

As illustrated in FIG. 5, in the initial state, the signal S1 is at a low level and thus the switch 20 (see FIG. 4) is in a disconnected state. Therefore, in the initial state, the output current (the current I1) of the light emitting element 3 is zero, and the light emitting element 3 is in a turn-off state.

In addition, in the initial state, the current I1 is zero and thus both the voltage V1 on the input side and the voltage V2 on the output side of the light emitting element 3 have values substantially equal to the power supply voltage Vcc+V_{L}.

Next, when the signal S1 is switched from a low level to a high level at a time T1, the switch 20 is brought into a conductive state, and thus a current starts to flow through the light emitting element 3. This causes the value of the current I1 to gradually increase from the time T1.

In addition, when the current starts to flow through the light emitting element 3 at the time T1, a potential difference is generated between the input side and the output side of the light emitting element 3, and thus the voltage V2 on the output side decreases.

Furthermore, as in the first modification, a great voltage drop occurs in the light emitting element 3 due to a change in the value of the current flowing through the parasitic inductor 5 in the light emitting element 3.

As a result, the voltage V2 on the output side of the light emitting element 3 greatly decreases to a voltage Val after the time T1. On the other hand, in the second modification, since the power supply voltage itself is boosted to Vcc+V_{L}, the value of the voltage Val is greater than the voltage Va of the first modification and is maintained at a value such that the mirror ratio of the constant current circuit 10 can be maintained.

Therefore, in the second modification, a current necessary for the light emitting element 3 can flow from the constant current circuit 10 more quickly, and thus the increase in the current I1 is promoted. Accordingly, in the second modification, the current I1 reaches a predetermined constant current Ia at a time T2a before the time T2 in the first modification.

As described above, in the second modification, the mirror ratio of the constant current circuit 10 can be maintained even at the time of the rise of the light emitting element 3 by boosting the power supply voltage itself, so that the rise time (T2a-T1 in FIG. 5) of the light emitting element 3 can be shortened.

The flow after the time T2a will be described. When the current I1 reaches the predetermined constant current Ia at the time T2a, the voltage drop due to the parasitic inductor 5 no longer occurs, and thus the voltage V2 on the output side of the light emitting element 3 increases and becomes constant at a voltage Vb1. Then, the light emitting element 3 maintains the lighting state.

Since the power supply voltage itself is boosted, the voltage Vb1 is greater than the voltage Vb in the first modification.

Next, when the signal S1 is switched from a high level to a low level at a time T3, the switch 20 is brought into a disconnected state, and thus the current flowing through the light emitting element 3 starts to decrease. As a result, the value of the current I1 gradually decreases from the time T3.

In addition, when the current in the light emitting element 3 starts to decrease at the time T3, a potential difference between the input side and the output side of the light emitting element 3 becomes small, and thus the voltage V2 on the output side increases.

Furthermore, since the parasitic inductor 5 is present in the light emitting element 3, a great voltage rise occurs in the light emitting element 3 due to a change in the value of the current flowing through the parasitic inductor 5.

As a result, the voltage V2 on the output side of the light emitting element 3 increases to a voltage Vd1 exceeding the power supply voltage Vcc+V_{L} after the time T3.

Then, when the value of the current I1 becomes zero at a time T4, the light emitting element 3 is turned off and returns to the initial state. In addition, when the current I1 becomes constant at zero at the time T4, the voltage rise due to the parasitic inductor 5 no longer occurs, and thus the voltage V2 on the output side of the light emitting element 3 returns to a value substantially equal to the power supply voltage Vcc+V_{L}.

Here, in the second modification, the value of the voltage V2 is the voltage Vb1 that is greater than that in the first modification during a period from the time T2a when the current I1 reaches the predetermined constant current Ia to the time T3. This increases the loss in the light emitting device 1, and thus the power consumption of the light emitting device 1 increases.

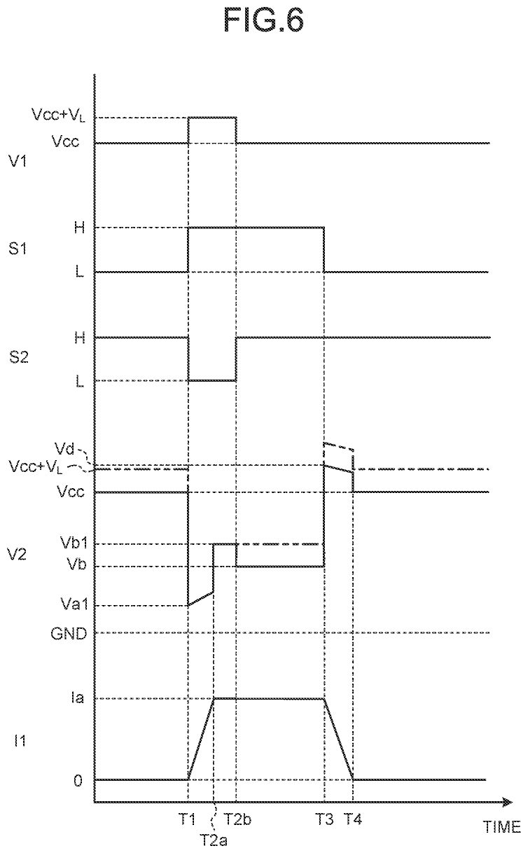

Next, the operation of the light emitting element driving circuit 2 according to the embodiment will be described with reference to FIGS. 1 and 6. FIG. 6 is a timing chart illustrating an operation example of the light emitting element driving circuit 2 according to the embodiment of the present disclosure, and illustrates the signal S2 in addition to the voltage V1, the signal S1, the voltage V2, and the current I1.

As illustrated in FIG. 1, the signal S2 is an external signal input to the input terminal of the inverter 32 in the booster circuit 30. In FIG. 6, in order to facilitate understanding, changes in the voltage V2 in the second reference example are indicated by two-dot chain lines.

As illustrated in FIG. 6, in the initial state, the signal S1 is at a low level and thus the switch 20 (see FIG. 1) is in a disconnected state. Therefore, in the initial state, the output current (the current I1) of the light emitting element 3 is zero, and the light emitting element 3 is in a turn-off state.

In addition, in the initial state, the current I1 is zero and thus both the voltage V1 on the input side and the voltage V2 on the output side of the light emitting element 3 have values substantially equal to the power supply voltage Vcc.

Furthermore, in the initial state, the signal S2 is at a high level, and thus the P-type transistor 32a is in a disconnected state and the N-type transistor 32b is in a conductive state. As a result, the power supply voltage Vcc and the ground voltage are applied respectively to both terminals of the capacitor 31, and the capacitor 31 is charged so that the potential difference between both terminals is a value substantially equal to the power supply voltage Vcc.

Next, when the signal S1 is switched from a low level to a high level at a time T1, the switch 20 is brought into a conductive state, and thus a current starts to flow through the light emitting element 3. This causes the value of the current I1 to gradually increase from the time T1.

In addition, at the time T1, the signal S2 is switched from the high level to a low level in synchronization with the signal S1. This brings the P-type transistor 32a into a conductive state and the N-type transistor 32b into a disconnected state, and thus the voltage of the output terminal (the node 32c) of the inverter 32 changes from zero to a voltage V_{L}.

As a result, the voltage V_{L} of the output terminal (the node 32c) of the inverter 32 is added to the potential difference (the voltage Vcc) between both terminals of the capacitor 31, and the voltage (that is, the voltage V1 on the input side of the light emitting element 3) of the node 33 is boosted to Vcc+V_{L}.

That is, in the embodiment, the voltage of the node 33 is boosted by the booster circuit 30 in synchronization with the timing (the time T1) at which the light emitting element 3 is turned on.

When the current starts to flow through the light emitting element 3 at the time T1, a potential difference is generated between the input side and the output side of the light emitting element 3, and thus the voltage V2 on the output side decreases. In addition, as in the second modification, a great voltage drop occurs in the light emitting element 3 due to a change in the value of the current flowing through the parasitic inductor 5 in the light emitting element 3.

As a result, the voltage V2 on the output side of the light emitting element 3 greatly decreases to a voltage Val after the time T1. On the other hand, in the embodiment, since the terminal (the voltage V1) on the input side of the light emitting element 3 is boosted, the value of the voltage V2 is maintained at a value (the voltage Val) such that the mirror ratio of the constant current circuit 10 can be maintained, as in the second modification.

Therefore, in the embodiment, a current necessary for the light emitting element 3 can flow from the constant current circuit 10 more quickly, and thus the increase in the current I1 is promoted and the current I1 reaches the predetermined constant current Ia at the time T2a, which is the same as the time in the second modification.

As described above, in the embodiment, a current based on the mirror ratio of the constant current circuit 10 can flow more quickly even at the time of the rise of the light emitting element 3 by boosting the terminal on the input side of the light emitting element 3 using the booster circuit 30, so that the rise time (T2a-T1) of the light emitting element 3 can be shortened.

The flow after the time T2a will be described. When the current I1 reaches the predetermined constant current Ia at the time T2a, the voltage drop due to the parasitic inductor 5 no longer occurs, and thus the voltage V2 on the output side of the light emitting element 3 increases and becomes constant at a voltage Vb1. Then, the light emitting element 3 maintains the lighting state.

Here, in the embodiment, the signal S2 is switched from the low level to the high level at a time T2b after the time T2a. As a result, the voltage of the output terminal (the node 32c) of the inverter 32 changes from the voltage V_{L} to zero, and thus the node 33 is no longer boosted by the capacitor 31.

That is, in the embodiment, the voltage V1 on the input side of the light emitting element 3 returns to a value substantially equal to the power supply voltage Vcc at the time T2b. As a result, the voltage V2 on the output side of the light emitting element 3 also decreases from the voltage Vb1 to the same voltage Vb as that in the first modification at the time T2b.

Next, when the signal S1 is switched from a high level to a low level at a time T3, the switch 20 is brought into a disconnected state, and thus the current flowing through the light emitting element 3 starts to decrease. As a result, the value of the current I1 gradually decreases from the time T3. The description of the subsequent flow will be omitted because it is the same as in the first modification.

Here, in the embodiment, the value of the voltage V2 can be reduced to the voltage Vb that is smaller than the voltage in the second modification during a period from the time T2b to the time T3. This can reduce the loss in the light emitting device 1, and thus reduce the power consumption of the light emitting device 1.

As described above, in the embodiment, the terminal on the input side of the light emitting element 3 is boosted by the booster circuit 30 in synchronization with the timing at which the light emitting element 3 is turned on, so that both the shortening of the rise time of the light emitting element 3 and the reduction of the power consumption can be achieved.

In addition, in the embodiment, the terminal on the input side of the light emitting element 3 can be stably boosted by constituting the booster circuit 30 using the capacitor 31 and the inverter 32.

Note that, in the embodiment, constituting the booster circuit 30 using the capacitor 31 and the inverter 32 is not necessarily required, and another known booster circuit may be used to boost the terminal on the input side of the light emitting element 3.

In addition, in the embodiment, the pair of high breakdown voltage transistors (the N-type transistor 11 and the N-type transistor 12) constitutes the current mirror, and thus the power supply voltage Vcc that is higher than the logic voltage V_{L} can be connected to the light emitting element 3.

Therefore, according to the embodiment, the driving current of the light emitting element 3 can be increased. Furthermore, in the embodiment, since the pair of high breakdown voltage transistors having substantially equal element characteristics constitutes the current mirror, a stable constant current having the mirror ratio of the current mirror close to the element size can be supplied to the light emitting element 3.

In addition, in the embodiment, the booster circuit 30 preferably boosts the node 33 at least during a period from the time when the current I1 flowing through the light emitting element 3 rises to the time when the current I1 becomes constant (that is, at least during a period from the time T1 to the time T2a).

If the boosting of the node 33 is stopped while the current I1 is rising (that is, before the time T2a), the voltage V2 on the output side of the light emitting element 3 decreases; thus, the mirror ratio of the constant current circuit 10 may not be maintained.

In that case, it becomes difficult to flow a current necessary for the light emitting element 3 from the constant current circuit 10, and thus the increase in the current I1 is suppressed; as a result, it takes a longer time for the current I1 to reach the predetermined constant current Ia.

However, in the embodiment, since the node 33 is boosted at least during a period from the time T1 to the time T2a, it is possible to suppress the extension of the time for the current I1 to reach the predetermined constant current Ia.

In addition, in the embodiment, the booster circuit 30 preferably stops the boosting of the node 33 during a period from before the current I1 flowing through the light emitting element 3 drops to after the current I1 has dropped (that is, at least during a period from before the time T3 to after the time T4).

If the boosting of the node 33 is stopped after the current I1 starts to drop (that is, after the time T3), it means that the node 33 has been boosted during a period from the time T2a to the time T3.

In this case, the constant current Ia flows through the light emitting element 3 and the voltage V2 is maintained at the voltage Vb1 during the period from the time T2a to the time T3, when the power consumption of the light emitting element 3 is the highest, and thus the loss in the light emitting device 1 increases; as a result, the power consumption of the light emitting device 1 increases.

However, in the embodiment, since the boosting of the node 33 is stopped at least before the time T3, it is possible to suppress the increase in the power consumption in the light emitting device 1.

In the embodiment, the boosting of the node 33 is preferably stopped promptly after the time T2a when the light emitting element 3 has risen. For example, when the rise time of the light emitting element 3 is Tr, the width of the signal S2 (that is, the period from the time T1 to the time T2b) is preferably set to be within the range of 1.1 Tr to 1.5 Tr. This can effectively suppress the increase in the power consumption in the light emitting device 1.

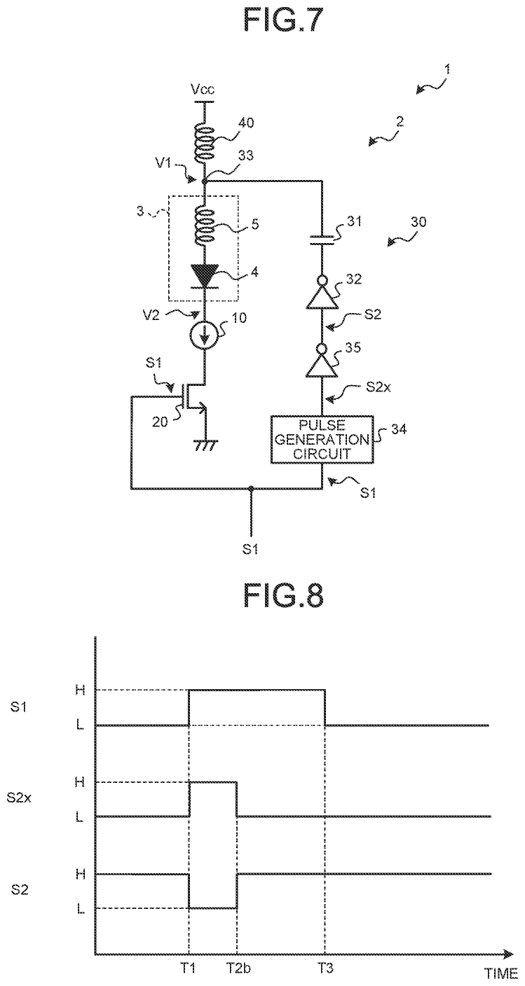

The timing of the boosting by the booster circuit 30 described above is controlled by the signal S2. Then, an example of a method of generating the signal S2 will be described with reference to FIGS. 7 and 8.

FIG. 7 is a circuit diagram illustrating a configuration example of the light emitting device 1 and the light emitting element driving circuit 2 according to the embodiment of the present disclosure, and illustrating the details of the circuit that generates the signal S2. In FIG. 7, the constant current circuit 10 is indicated by one symbol as a constant current source.

In the example in FIG. 7, the booster circuit 30 includes a pulse generation circuit 34 and an inverter 35 in addition to the capacitor 31 and the inverter 32 described above.

The pulse generation circuit 34 generates a pulse signal having a predetermined width. The pulse generation circuit 34 internally has, for example, an edge detection circuit and a delay circuit (not illustrated), and generates a rising pulse signal synchronized with a rising edge of the input signal. In addition, the pulse generation circuit 34 generates a pulse signal having a width based on a delay time set in advance in the internal delay circuit.

As illustrated in FIG. 7, the signal S1 is input to the gate of the switch 20 from a control unit (not illustrated), and the disconnection or connection by the switch 20 is controlled. In addition, the signal S1 is also input to the pulse generation circuit 34.

Then, the pulse generation circuit 34 outputs a signal S2x to the inverter 35 based on the input signal S1. As illustrated in FIG. 8, the signal S2x is a pulse signal having the same rise timing (the time T1 in this case) as the signal S1 and having a width from the time T1 to the time T2b. FIG. 8 is a timing chart illustrating an operation example of each signal according to the embodiment of the present disclosure.

Then, as illustrated in FIG. 7, the inverter 35 to which the signal S2x is input outputs the signal S2 (see FIG. 8) obtained by inverting the signal S2x to the inverter 32.

As described above, the rise of the light emitting element 3 and the booster circuit 30 can be accurately synchronized with each other by generating the signal S2 based on the signal S1. Note that the example in FIG. 7 is merely an example, and the signal S2 may be generated from the signal S1 using a circuit other than the pulse generation circuit 34 and the inverter 35.

In addition, in the above-described embodiment, an example has been described in which the source of the P-type transistor 32a is connected to the logic voltage V_{L}, so that the booster circuit 30 performs the boosting by the voltage V_{L}; however, the voltage that can be boosted by the booster circuit 30 is not limited to the voltage V_{L}.

For example, the source of the P-type transistor 32a may be connected to the power supply voltage Vcc, or the source of the P-type transistor 32a may be connected to another voltage source.

[Various Modifications]

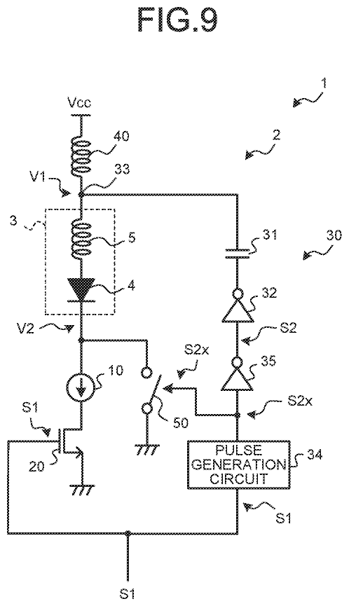

Next, various modifications of the embodiment will be described with reference to FIGS. 9 to 11. FIG. 9 is a circuit diagram illustrating a configuration example of a light emitting device 1 and a light emitting element driving circuit 2 according to a first modification of the embodiment of the present disclosure, and corresponding to FIG. 7 of the embodiment.

As illustrated in FIG. 9, the light emitting element driving circuit 2 of the first modification is different from that of the embodiment in that an assist switch 50 is provided. The assist switch 50 is connected between a point between the light emitting element 3 and the constant current circuit 10, and a ground potential. That is, the assist switch 50 is connected between the terminal on the output side of the light emitting element 3 and the ground potential.

In addition, the assist switch 50 is disconnected or connected based on the signal S2x output from the pulse generation circuit 34. That is, the assist switch 50 performs conduction in synchronization with the boosting operation of the booster circuit 30. For example, the assist switch 50 is an N-type transistor, and the signal S2x is input to the gate of the N-type transistor.

In the first modification, the assist switch 50 performs conduction in synchronization with the boosting operation of the booster circuit 30 and thereby can assist the operation of the constant current circuit 10 with the on-resistance of the assist switch 50 when the voltage V2 on the output side of the light emitting element 3 decreases and the operation of the constant current circuit 10 is weakened.

Therefore, according to the first modification, the increase in the current I1 is further promoted, and thus the rise time of the light emitting element 3 can be further shortened.

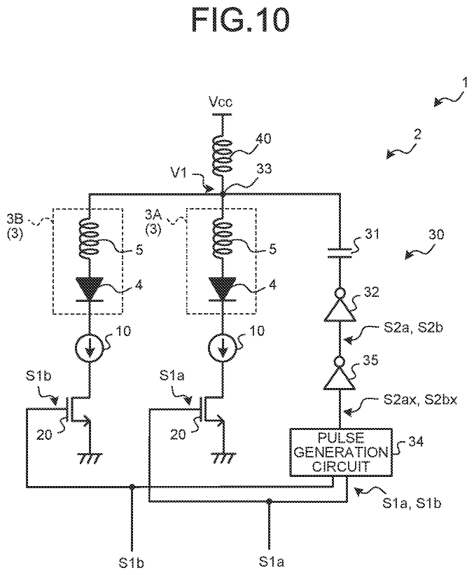

FIG. 10 is a circuit diagram illustrating a configuration example of a light emitting device 1 and a light emitting element driving circuit 2 according to a second modification of the embodiment of the present disclosure, and corresponding to FIG. 7 of the embodiment.

As illustrated in FIG. 10, in the light emitting element driving circuit 2 of the second modification, one booster circuit 30 is commonly connected to a plurality of light emitting elements 3A and 3B connected in parallel between the power supply voltage Vcc and the ground potential.

In the second modification, the light emitting element 3A is disconnected or connected by a signal S1a from the outside, and the light emitting element 3B is disconnected or connected by a signal S1b from the outside. These signals S1a and S1b are both input to the pulse generation circuit 34 of the second modification.

With such a configuration, the booster circuit 30 of the second modification can input both the signal S2a corresponding to the signal S1a and the signal S2b corresponding to the signal S1b to the inverter 32.

That is, the booster circuit 30 of the second modification can boost the node 33 at the timing at which the light emitting element 3A emits light and can boost the node 33 at the timing at which the light emitting element 3B emits light.

Therefore, according to the second modification, the terminals on the input side of the plurality of light emitting elements 3A and 3B can be both boosted by one booster circuit 30.

As described above, in the light emitting element driving circuit 2 of the second modification, since one booster circuit 30 can be shared by the plurality of light emitting elements 3A and 3B, the chip area of the light emitting element driving circuit 2 can be reduced.

In the example in FIG. 10, an example has been described in which one booster circuit 30 is shared by two light emitting elements 3A and 3B; however, the number of light emitting elements 3 sharing one booster circuit 30 is not limited to two, and one booster circuit 30 may be shared by three or more light emitting elements 3.

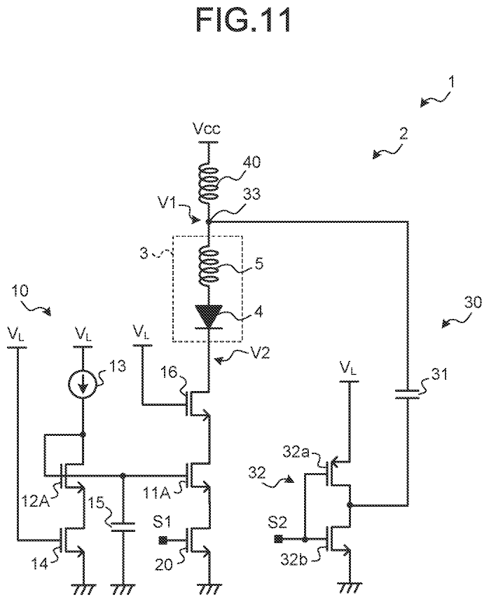

FIG. 11 is a circuit diagram illustrating a configuration example of a light emitting device 1 and a light emitting element driving circuit 2 according to a third modification of the embodiment of the present disclosure, and corresponding to FIG. 1 of the embodiment. As illustrated in FIG. 11, the light emitting element driving circuit 2 of the third modification is different in the circuit configuration of the constant current circuit 10 from that of the embodiment.

As illustrated in FIG. 11, the constant current circuit 10 has an N-type transistor 11A, an N-type transistor 12A, the constant current source 13, the N-type transistor 14, the capacitor 15, and an N-type transistor 16.

The N-type transistor 11A and the N-type transistor 12A are provided in place of the N-type transistor 11 and the N-type transistor 12 of the embodiment. The N-type transistor 11A and the N-type transistor 12A are low breakdown voltage transistors having substantially equal element characteristics, and constitute a current mirror.

In addition, the N-type transistor 16 separately added to the embodiment is a high breakdown voltage transistor (for example, LDMOS), and is connected between the N-type transistor 11A and the light emitting element 3.

That is, the drain of the N-type transistor 16 is connected to the terminal on the output side of the light emitting element 3, and the source of the N-type transistor 16 is connected to the drain of the N-type transistor 11A. In addition, a voltage V_{L} for logic operation is connected to the gate of the N-type transistor 14.

With such a circuit configuration, the constant current circuit 10 of the third modification can cause a constant current to flow through the N-type transistor 11A based on the constant current flowing from the constant current source 13 to the N-type transistor 12. As a result, the constant current circuit 10 of the third modification can supply a constant current to the light emitting element 3 connected in series with the N-type transistor 11A.

In addition, in the constant current circuit 10 of the third modification, the high breakdown voltage transistor (the N-type transistor 16) is connected to the terminal on the output side of the light emitting element 3, and thus the power supply voltage Vcc that is higher than the logic voltage V_{L} can be connected to the light emitting element 3. Therefore, according to the third modification, the driving current of the light emitting element 3 can be increased.

Furthermore, in the third modification, the number of high breakdown voltage transistors, which require a larger area than low breakdown voltage transistors, can be reduced in the constant current circuit 10 (two units in the embodiment and one unit in the third modification). Therefore, according to the third modification, the chip area of the light emitting element driving circuit 2 can be reduced.

In the constant current circuit 10 of the third modification, since the voltage connected to the N-type transistor 12A is not the power supply voltage Vcc but the logic voltage V_{L}, there is no particular problem even if a low breakdown voltage transistor is used for the N-type transistor 12A.

[Effects]

The light emitting element driving circuit 2 according to the embodiment includes the constant current circuit 10, the switch 20, and the booster circuit 30. The constant current circuit 10 supplies the constant current Ia to the light emitting element 3 from the power supply voltage Vcc. The switch 20 disconnects or connects the current I1 flowing through the light emitting element 3 based on an external signal (the signal S2). The booster circuit 30 boosts a voltage between the power supply voltage Vcc and the light emitting element 3 in synchronization with the timing at which the light emitting element 3 is turned on.

With this configuration, it is possible to achieve both the shortening of the rise time of the light emitting element 3 and the reduction of power consumption.

In addition, in the light emitting element driving circuit 2 according to the embodiment, the booster circuit 30 boosts a voltage between the power supply voltage Vcc and the light emitting element 3 during a period from the time when the current I1 flowing through the light emitting element 3 rises to the time when the current I1 becomes constant.

With this configuration, it is possible to suppress the extension of the time for the current I1 flowing through the light emitting element 3 to reach the predetermined constant current Ia.

In the light emitting element driving circuit 2 according to the embodiment, the booster circuit 30 stops the boosting of the voltage between the power supply voltage Vcc and the light emitting element 3 during a period from before the current I1 flowing through the light emitting element 3 drops to after the current I1 has dropped.

With this configuration, it is possible to suppress the increase in the power consumption in the light emitting device 1.

In the light emitting element driving circuit 2 according to the embodiment, the booster circuit 30 includes the capacitor 31 and the inverter 32. In addition, one terminal of the capacitor 31 is connected between the power supply voltage Vcc and the light emitting element 3, and the other terminal of the capacitor 31 is connected to the output terminal (the node 32c) of the inverter 32.

With this configuration, the terminal on the input side of the light emitting element 3 can be stably boosted.

In addition, in the light emitting element driving circuit 2 according to the embodiment, the constant current circuit 10 has the pair of high breakdown voltage transistors (the N-type transistors 11, 12) constituting a current mirror.

With this configuration, it is possible to increase the driving current of the light emitting element 3 and supply a stable constant current in which the mirror ratio of the current mirror is close to the element size to the light emitting element 3.

In addition, in the light emitting element driving circuit 2 according to the embodiment, the constant current circuit 10 has the pair of low breakdown voltage transistors (the N-type transistors 11A, 12A) constituting a current mirror. Furthermore, the constant current circuit 10 has the high breakdown voltage transistor (the N-type transistor 16) connected between one of the low breakdown voltage transistors and the light emitting element 3.

With this configuration, it is possible to reduce the chip area of the light emitting element driving circuit 2.

In addition, the light emitting element driving circuit 2 according to the embodiment further includes the assist switch 50 that is connected between a point between the light emitting element 3 and the constant current circuit 10, and the ground potential, and performs conduction in synchronization with the boosting operation of the booster circuit 30.

With this configuration, it is possible to further shorten the rise time of the light emitting element 3.

In addition, the light emitting element driving circuit 2 according to the embodiment includes the plurality of light emitting elements 3, and the booster circuit 30 boosts the plurality of light emitting elements 3 connected in parallel to the power supply voltage Vcc in common.

With this configuration, it is possible to reduce the chip area of the light emitting element driving circuit 2.

Although the embodiments of the present disclosure have been described above, the technical scope of the present disclosure is not limited to the above-described embodiments as it is, and various modifications can be made without departing from the gist of the present disclosure. In addition, components of different embodiments and modifications may be appropriately combined.

Furthermore, the effects described herein are merely examples and are not subject to limitations, and other effects may be provided.

The present technique may also have the following configurations:

(1)

A light emitting element driving circuit comprising:

a constant current circuit that supplies a constant current from a power supply voltage to a light emitting element;

a switch that disconnects or connects a current flowing through the light emitting element based on an external signal; and

a booster circuit that boosts a voltage between the power supply voltage and the light emitting element in synchronization with a timing at which the light emitting element is turned on.

(2)

The light emitting element driving circuit according to (1), wherein

the booster circuit boosts a voltage between the power supply voltage and the light emitting element during a period from a time when the current flowing through the light emitting element rises to a time when the current becomes constant.

(3)

The light emitting element driving circuit according to (1) or (2), wherein

the booster circuit stops the boosting of the voltage between the power supply voltage and the light emitting element during a period from before the current flowing through the light emitting element drops to after the current has dropped.

(4)

The light emitting element driving circuit according to any one of (1) to (3), wherein

the booster circuit has a capacitor and an inverter, and

one terminal of the capacitor is connected between the power supply voltage and the light emitting element, and the other terminal of the capacitor is connected to an output terminal of the inverter.

(5)

The light emitting element driving circuit according to any one of (1) to (4), wherein

the constant current circuit has a pair of high breakdown voltage transistors constituting a current mirror.

(6)

The light emitting element driving circuit according to any one of (1) to (4), wherein

the constant current circuit has a pair of low breakdown voltage transistors constituting a current mirror, and a high breakdown voltage transistor connected between one of the low breakdown voltage transistors and the light emitting element.

(7)

The light emitting element driving circuit according to any one of (1) to (6), further comprising

an assist switch that is connected between a point between the light emitting element and the constant current circuit, and a ground potential, and performs conduction in synchronization with a boosting operation of the booster circuit.

(8)

The light emitting element driving circuit according to any one of (1) to (7), further comprising

a plurality of the light emitting elements, wherein

the booster circuit boosts the plurality of light emitting elements connected in parallel to the power supply voltage in common.

(9)

A light emitting device comprising:

a light emitting element; and

a light emitting element driving circuit having a constant current circuit that supplies a constant current to the light emitting element from a power supply voltage, a switch that disconnects or connects a current flowing through the light emitting element based on an external signal, and a booster circuit that boosts a voltage between the power supply voltage and the light emitting element in synchronization with a timing at which the light emitting element is turned on.

(10)

The light emitting device according to (9), wherein

the booster circuit boosts a voltage between the power supply voltage and the light emitting element during a period from a time when the current flowing through the light emitting element rises to a time when the current becomes constant.

(11)

The light emitting device according to (9) or (10), wherein

the booster circuit stops the boosting of the voltage between the power supply voltage and the light emitting element during a period from before the current flowing through the light emitting element drops to after the current has dropped.

(12)

The light emitting device according to any one of (9) to (11), wherein

the booster circuit has a capacitor and an inverter, and

one terminal of the capacitor is connected between the power supply voltage and the light emitting element, and the other terminal of the capacitor is connected to an output terminal of the inverter.

(13)

The light emitting device according to any one of (9) to (12), wherein

the constant current circuit has a pair of high breakdown voltage transistors constituting a current mirror.

(14)

The light emitting device according to any one of (9) to (12), wherein

the constant current circuit has a pair of low breakdown voltage transistors constituting a current mirror, and a high breakdown voltage transistor connected between one of the low breakdown voltage transistors and the light emitting element.

(15)

The light emitting device according to any one of (9) to (14), further including

an assist switch that is connected between a point between the light emitting element and the constant current circuit, and a ground potential, and performs conduction in synchronization with a boosting operation of the booster circuit.

(16)

The light emitting device according to any one of (9) to (15), including

a plurality of the light emitting elements, wherein the booster circuit boosts the plurality of light emitting elements connected in parallel to the power supply voltage in common.

### REFERENCE SIGNS LIST

1 LIGHT EMITTING DEVICE
2 LIGHT EMITTING ELEMENT DRIVING CIRCUIT
3 LIGHT EMITTING ELEMENT
4 DIODE
5 PARASITIC INDUCTOR
10 CONSTANT CURRENT CIRCUIT
20 SWITCH
30 BOOSTER CIRCUIT
31 CAPACITOR
32 INVERTER
40 INDUCTOR ELEMENT
50 ASSIST SWITCH
I1 CURRENT
S1 SIGNAL (EXAMPLE OF EXTERNAL SIGNAL)

1. A light emitting element driving circuit comprising:
a constant current circuit that supplies a constant current from a power supply voltage to a light emitting element;
a switch that disconnects or connects a current flowing through the light emitting element based on an external signal; and
a booster circuit that boosts a voltage between the power supply voltage and the light emitting element in synchronization with a timing at which the light emitting element is turned on.

2. The light emitting element driving circuit according to claim 1, wherein
the booster circuit boosts a voltage between the power supply voltage and the light emitting element during a period from a time when the current flowing through the light emitting element rises to a time when the current becomes constant.

3. The light emitting element driving circuit according to claim 1, wherein
the booster circuit stops the boosting of the voltage between the power supply voltage and the light emitting element during a period from before the current flowing through the light emitting element drops to after the current has dropped.

4. The light emitting element driving circuit according to claim 1, wherein
the booster circuit has a capacitor and an inverter, and
one terminal of the capacitor is connected between the power supply voltage and the light emitting element, and the other terminal of the capacitor is connected to an output terminal of the inverter.

5. The light emitting element driving circuit according to claim 1, wherein
the constant current circuit has a pair of high breakdown voltage transistors constituting a current mirror.

6. The light emitting element driving circuit according to claim 1, wherein
the constant current circuit has a pair of low breakdown voltage transistors constituting a current mirror, and a high breakdown voltage transistor connected between one of the low breakdown voltage transistors and the light emitting element.

7. The light emitting element driving circuit according to claim 1, further comprising
an assist switch that is connected between a point between the light emitting element and the constant current circuit, and a ground potential, and performs conduction in synchronization with a boosting operation of the booster circuit.

8. The light emitting element driving circuit according to claim 1, further comprising
a plurality of the light emitting elements, wherein
the booster circuit boosts the plurality of light emitting elements connected in parallel to the power supply voltage in common.

9. A light emitting device comprising:
a light emitting element; and
a light emitting element driving circuit having a constant current circuit that supplies a constant current to the light emitting element from a power supply voltage, a switch that disconnects or connects a current flowing through the light emitting element based on an external signal, and a booster circuit that boosts a voltage between the power supply voltage and the light emitting element in synchronization with a timing at which the light emitting element is turned on.
